(19) United States
(12) Patent Application Publication
(10) Pub. No.: US 2010/0282316 A1
(43) Pub. Date: Nov. 11, 2010

(54) Solar Cell Concentrator Structure Including A Plurality of Glass Concentrator Elements With A Notch Design

(75) Inventors: Kevin R. Gibson, Redwood City, CA (US); Abhay Maheshwari, Monte Sereno, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Solaria Corporation, Fremont, CA (US)

(21) Appl. No.: 12/687,862

(22) Filed: Jan. 14, 2010

Related U.S. Application Data
(63) Continuation-in-part of application No. 11/695,566, filed on Apr. 2, 2007, now abandoned.

(51) Int. Cl. H01L 31/0232; H01L 31/18

(52) U.S. Cl. 136/259; 438/14; 257/E31.127

(57) ABSTRACT

A solar concentrator structure including a plurality of glass concentrator elements with a notch design. According to an embodiment, the present invention provides a solar cell concentrator structure. The structure includes an outside surface. The structure also includes an inside surface, the inside surface being substantially flat. The structure includes a first concentrator element integrally formed on the outside surface, the first concentrator element having a first curved surface, the curved surface being characterized by a radius of at least 1 mm, the curved surface having a first flat region of at least 0.25 mm, the flat region being at least 4 mm from the inside surface. The structure includes a second concentrator element integrally formed with the first concentrator element and the outside surface, the second concentrator element including a second curved surface and a second flat region.

### CROSS-REFERENCES TO RELATED APPLICATIONS

The present application is a continuation-in-part application claiming priority to U.S. patent application Ser. No. 11/695,566, filed Apr. 2, 2007, which is incorporated by reference herein for all purposes.

### STATEMENT AS TO RIGHTS TO INVENTIONS MADE UNDER FEDERALLY SPONSORED RESEARCH OR DEVELOPMENT

NOT APPLICABLE

### REFERENCE TO A “SEQUENCE LISTING,” A TABLE, OR A COMPUTER PROGRAM LISTING APPENDIX SUBMITTED ON A COMPACT DISK

NOT APPLICABLE

### BACKGROUND OF THE INVENTION

The present invention relates generally to solar energy techniques. In particular, the present invention provides a method and resulting device fabricated from a plurality of concentrating elements respectively coupled to a plurality of photovoltaic regions. More particularly, the present method and structure are directed solar panels with solar concentrator elements integrated solar concentrators consisting essentially of glass material. Merely by way of example, the invention has been applied to solar panels, commonly termed modules, but it would be recognized that the invention has a much broader range of applicability.

As the population of the world increases, industrial expansion has lead to an equally large consumption of energy. Energy often comes from fossil fuels, including coal and oil, hydroelectric plants, nuclear sources, and others. As merely an example, the International Energy Agency projects further increases in oil consumption, with developing nations such as China and India accounting for most of the increase. Almost every element of our daily lives depends, in part, on oil, which is becoming increasingly scarce. As time further progresses, an era of “cheap” and plentiful oil is coming to an end. Accordingly, other and alternative sources of energy have been developed.

Concurrent with oil, we have also relied upon other very useful sources of energy such as hydroelectric, nuclear, and the like to provide our electricity needs. As an example, most of our conventional electricity requirements for home and business use come from turbines run on coal or other forms of fossil fuel, nuclear power generation plants, and hydroelectric plants, as well as other forms of renewable energy. Often times, home and business use of electrical power has been stable and widespread.

Most importantly, much if not all of the useful energy found on the Earth comes from our sun. Generally all common plant life on the Earth achieves life using photosynthesis processes from sun light. Fossil fuels such as oil were also developed from biological materials derived from energy associated with the sun. For human beings including “sun worshipers,” sunlight has been essential. For life on the planet Earth, the sun has been our most important energy source and fuel for modern day solar energy.

Solar energy possesses many characteristics that are very desirable! Solar energy is renewable, clean, abundant, and often widespread. Certain technologies developed often capture solar energy, concentrate it, store it, and convert it into other useful forms of energy.

Solar panels have been developed to convert sunlight into energy. As merely an example, solar thermal panels often convert electromagnetic radiation from the sun into thermal energy for heating homes, running certain industrial processes, or driving high grade turbines to generate electricity. As another example, solar photovoltaic panels convert sunlight directly into electricity for a variety of applications. Solar panels are generally composed of an array of solar cells, which are interconnected to each other. The cells are often arranged in series and/or parallel groups of cells in series. Accordingly, solar panels have great potential to benefit our nation, security, and human users. They can even diversify our energy requirements and reduce the world's dependence on oil and other potentially detrimental sources of energy.

Although solar panels have been used successful for certain applications, there are still certain limitations. Solar cells are often costly. Depending upon the geographic region, there are often financial subsidies from governmental entities for purchasing solar panels, which often cannot compete with the direct purchase of electricity from public power companies. Additionally, the panels are often composed of silicon bearing wafer materials. Such wafer materials are often costly and difficult to manufacture efficiently on a large scale. Availability of solar panels is also somewhat scarce. That is, solar panels are often difficult to find and purchase from limited sources of photovoltaic silicon bearing materials. These and other limitations are described throughout the present specification, and may be described in more detail below.

From the above, it is seen that techniques for improving solar devices is highly desirable.

### BRIEF SUMMARY OF THE INVENTION

The present invention relates generally to solar energy techniques. In particular, the present invention provides a method and resulting device fabricated from a plurality of concentrating elements respectively coupled to a plurality of photovoltaic regions. More particularly, the present method and structure are directed solar panels with solar concentrator elements integrated solar concentrators consisting essentially of glass material. Merely by way of example, the invention has been applied to solar panels, commonly termed modules, but it would be recognized that the invention has a much broader range of applicability.

According to an embodiment, the present invention provides a solar cell concentrator structure. The structure includes an outside surface. The structure also includes an inside surface, the inside surface being substantially flat. The structure includes a first concentrator element integrally formed on the outside surface, the first concentrator element having a first curved surface, the curved surface being characterized by a radius of at least 2 mm, the curved surface having a first flat region of at least 1 mm, the flat region being at least 4 mm from the inside surface. The structure includes a second concentrator element integrally formed with the first concentrator element and the outside surface, the second concentrator element including a second curved surface and a second flat region. The structure further includes a separation region provided between the first concentrator element and the second concentrator element, the separation region being characterized by a width of at least 2 mm separating the first flat region from the second flat region. The structure additionally includes a refractive index of about 1 characterizing the separation region.

According to another embodiment, the present invention provides a solar cell concentrator structure. The solar cell concentrator structure includes a piece of optical material characterized by a first spatial direction and a second spatial direction, the first spatial direction being normal to the second spatial direction. The structure also includes a first concentrator element and a second concentrator element integrally formed on a first portion of the piece of optical material and a second portion of the piece of optical material, respectively, defined along the second spatial direction, the first concentrator element having a first curved surface, the first curved surface being characterized by a radius of curvature of at least 1 mm, the curved surface having a first flat region of at least 0.25 mm, the flat region being at least 4 mm from the inside surface. The structure also includes an aperture region provided on the first curved surface, the curved surface being adapted to allow electromagnetic radiation to be illuminated thereon. The structure further includes an exit region provided on a second surface region of the piece of optical material, the exit region being adapted to allow electromagnetic radiation to be outputted, the second surface region being substantially flat. The structure additionally includes a separation region provided between the first concentrator element and the second concentrator element.

According to yet another embodiment, the present invention provides a method for manufacturing a solar cell. The method includes providing a piece of glass material, the piece of glass material being substantially flat, the piece of class having a first surface and a second surface. The method also includes providing a pattern for forming concentrator elements on the piece of the glass material. The method additionally includes overlay the piece of glass on the pattern, the first surface contacting the pattern. The method further includes subjecting the piece of glass to a high temperature. The method also includes forming a first concentrator element and a second concentrator on the first surface, the first concentrator element having a first curved surface, the first curved surface being characterized by a radius of curvature of at least 1 mm, the curved surface having a first flat region of at least 0.25 mm, the flat region being at least 4 mm from the inside surface. The method includes providing a first photovoltaic strip and a second photovoltaic strip on the second surface of the piece of class material; the first photovoltaic strip and the second photovoltaic strip being respectively aligned to the first concentrator element and the second concentrator element. The method also includes providing a back cover.

Many benefits are achieved by way of the present invention over conventional techniques. For example, the present technique provides an easy to use process that relies upon conventional technology such as silicon materials, although other materials can also be used. Additionally, the method provides a process that is compatible with conventional process technology without substantial modifications to conventional equipment and processes. Preferably, the invention provides for an improved solar cell, which is less costly and easy to handle. Such solar cell uses a plurality of photovoltaic regions, which are sealed within one or more substrate structures according to a preferred embodiment. In a preferred embodiment, the invention provides a method and completed solar cell structure using a plurality of photovoltaic strips free and clear from a module or panel assembly, which are provided during a later assembly process. Also in a preferred embodiment, one or more of the solar cells have less silicon per area (e.g., 80% or less, 50% or less) than conventional solar cells. In preferred embodiments, the present method and cell structures are also light weight and not detrimental to building structures and the like. That is, the weight is about the same or slightly more than conventional solar cells at a module level according to a specific embodiment. In a preferred embodiment, the present solar cell using the plurality of photovoltaic strips can be used as a “drop in” replacement of conventional solar cell structures. As a drop in replacement, the present solar cell can be used with conventional solar cell technologies for efficient implementation according to a preferred embodiment. Depending upon the embodiment, one or more of these benefits may be achieved. These and other benefits will be described in more detail throughout the present specification and more particularly below.

Various additional objects, features and advantages of the present invention can be more fully appreciated with reference to the detailed description and accompanying drawings that follow.

### BRIEF DESCRIPTION OF THE DRAWINGS

FIG. 1 is a simplified diagram of a solar cell according to an embodiment of the present invention;

FIG. 2 is a simplified diagram of solar cell concentrating elements according to an embodiment of the present invention;

FIG. 2A is a simplified side-view diagram of solar cell concentrating elements according to an embodiment of the present invention;

FIG. 3 is a simplified diagram of a plurality of notch structures for a solar cell concentrator according to an embodiment of the present invention;

FIG. 4 is a more detailed diagram of a notch structure for a solar cell concentrator according to an embodiment of the present invention; and

FIG. 5 is a plot of irradiation loss as a function of notch structure size according to an embodiment of the present invention.

FIG. 6 is a plot of irradiation loss as a function of notch size is according to an embodiment of the present invention.

FIG. 7 is a simplified diagram illustrating a solar concentrator according to an embodiments of the present invention.

FIG. 8 is a simplified diagram illustrating operation of solar concentrator according to an embodiment of the present invention.

FIG. 9 is a simplified diagram illustrating operation of a solar panel with solar concentrator according to an embodiment of the present invention.

FIG. 10 is simplified diagram illustrating the shape of a concentrator element in relation to a photovoltaic device according to an embodiment of the present invention.

FIGS. 11A and 11B are simplified diagrams illustrating shapes and dimensions of concentrator elements according to an embodiment of the present invention.

FIG. 11C is a simplified diagram providing an exploded view of a concentrated solar panel according to an embodiment of the present invention.

FIG. 12-16 are diagrams illustrating the optical properties concentrator elements according to embodiments of the present invention.

FIG. 17 is a simplified diagram illustrating a curved concentrator shape according to an embodiment of the present invention.

FIGS. 18A and 18B are simplified diagram illustrating solar panel designs where same concentrator design is used to provide different concentrator ratios according to an embodiment of the present invention.

FIG. 19 is a simplified diagram illustrating a process for forming solar concentrator according to an embodiment of the present invention.

FIG. 20 is a simplified diagram illustrating a glass concentrator design according to an embodiment of the present invention.

FIG. 21 is a simplified diagram illustrating geometry of glass concentrator according to embodiments of the present invention.

### DETAILED DESCRIPTION OF THE INVENTION

The present invention relates generally to solar energy techniques. In particular, the present invention provides a method and resulting device fabricated from a plurality of concentrating elements respectively coupled to a plurality of photovoltaic regions. More particularly, the present method and structure are directed solar panels with solar concentrator elements integrated solar concentrators consisting essentially of glass material. Merely by way of example, the invention has been applied to solar panels, commonly termed modules, but it would be recognized that the invention has a much broader range of applicability.

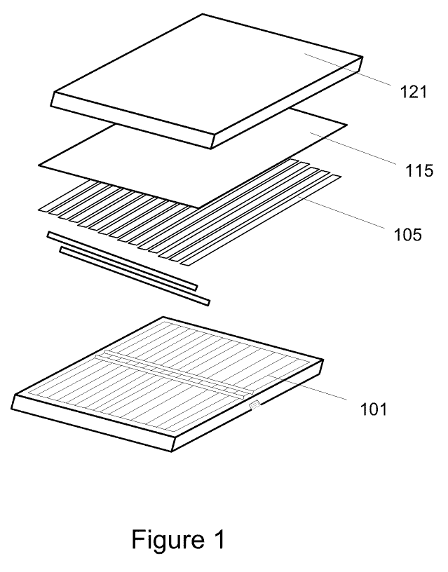

FIG. 1 is a simplified diagram of a solar cell according to an embodiment of the present invention. This diagram is merely an example, which should not unduly limit the scope of the claims herein. One of ordinary skill in the art would recognize other variations, modifications, and alternatives. As shown is an expanded view of the present solar cell device structure, which includes various elements. The device has a back cover member 101, which includes a surface area and a back area. The back cover member also has a plurality of sites, which are spatially disposed, for electrical members, such as bus bars, and a plurality of photovoltaic regions. Alternatively, the back cover can be free from any patterns and is merely provided for support and packaging. Of course, there can be other variations, modifications, and alternatives.

In a preferred embodiment, the device has a plurality of photovoltaic strips 105, each of which is disposed overlying the surface area of the back cover member. In a preferred embodiment, the plurality of photovoltaic strips correspond to a cumulative area occupying a total photovoltaic spatial region, which is active and converts sunlight into electrical energy.

An encapsulating material 115 is overlying a portion of the back cover member. That is, an encapsulating material forms overlying the plurality of strips, and exposed regions of the back cover, and electrical members. In a preferred embodiment, the encapsulating material can be a single layer, multiple layers, or portions of layers, depending upon the application. In alternative embodiments, as noted, the encapsulating material can be provided overlying a portion of the photovoltaic strips or a surface region of the front cover member, which would be coupled to the plurality of photovoltaic strips. Of course, there can be other variations, modifications, and alternatives.

In a specific embodiment, a front cover member 121 is coupled to the encapsulating material. That is, the front cover member is formed overlying the encapsulate to form a multilayered structure including at least the back cover, bus bars, plurality of photovoltaic strips, encapsulate, and front cover. In a preferred embodiment, the front cover includes one or more concentrating elements, which concentrate (e.g., intensify per unit area) sunlight onto the plurality of photovoltaic strips. That is, each of the concentrating elements can be associated respectively with each of or at least one of the photovoltaic strips.

Upon assembly of the back cover, bus bars, photovoltaic strips, encapsulate, and front cover, an interface region is provided along at least a peripheral region of the back cover member and the front cover member. The interface region may also be provided surrounding each of the strips or certain groups of the strips depending upon the embodiment. The device has a sealed region and is formed on at least the interface region to form an individual solar cell from the back cover member and the front cover member. The sealed region maintains the active regions, including photovoltaic strips, in a controlled environment free from external effects, such as weather, mechanical handling, environmental conditions, and other influences that may degrade the quality of the solar cell. Additionally, the sealed region and/or sealed member (e.g., two substrates) protect certain optical characteristics associated with the solar cell and also protects and maintains any of the electrical conductive members, such as bus bars, interconnects, and the like. Of course, there can be other benefits achieved using the sealed member structure according to other embodiments.

In a preferred embodiment, the total photovoltaic spatial region occupies a smaller spatial region than the surface area of the back cover. That is, the total photovoltaic spatial region uses less silicon than conventional solar cells for a given solar cell size. In a preferred embodiment, the total photovoltaic spatial region occupies about 80% and less of the surface area of the back cover for the individual solar cell. Depending upon the embodiment, the photovoltaic spatial region may also occupy about 70% and less or 60% and less or preferably 50% and less of the surface area of the back cover or given area of a solar cell. Of course, there can be other percentages that have not been expressly recited according to other embodiments. Here, the terms “back cover member” and “front cover member” are provided for illustrative purposes, and not intended to limit the scope of the claims to a particular configuration relative to a spatial orientation according to a specific embodiment. Further details of each of the various elements in the solar cell can be found throughout the present specification and more particularly below.

In a specific embodiment, the present invention provides a packaged solar cell assembly being capable of stand-alone operation to generate power using the packaged solar cell assembly and/or with other solar cell assemblies. The packaged solar cell assembly includes rigid front cover member having a front cover surface area and a plurality of concentrating elements thereon. Depending upon applications, the rigid front cover member consist of a variety of materials. For example, the rigid front cover is made of polymer material. As another example, the rigid front cover is made of transparent polymer material having a reflective index of about 1.4 or 1.42 or greater. According to an example, the rigid front cover has a Young's Modulus of a suitable range. Each of the concentrating elements has a length extending from a first portion of the front cover surface area to a second portion of the front cover surface area. Each of the concentrating elements has a width provided between the first portion and the second portion. Each of the concentrating elements having a first edge region coupled to a first side of the width and a second edge region provided on a second side of the width. The first edge region and the second edge region extend from the first portion of the front cover surface area to a second portion of the front cover surface area. The plurality of concentrating elements is configured in a parallel manner extending from the first portion to the second portion.

It is to be appreciated that embodiment can have many variations. For example, the embodiment may further includes a first electrode member that is coupled to a first region of each of the plurality of photovoltaic strips and a second electrode member coupled to a second region of each of the plurality of photovoltaic strips.

As another example, the solar cell assembly additionally includes a first electrode member coupled to a first region of each of the plurality of photovoltaic strips and a second electrode member coupled to a second region of each of the plurality of photovoltaic strips. The first electrode includes a first protruding portion extending from a first portion of the sandwiched assembly and the second electrode comprising a second protruding portion extending from a second portion of the sandwiched assembly.

In yet another specific embodiment, the present invention provides a solar cell apparatus. The solar cell apparatus includes a backside substrate member comprising a backside surface region and an inner surface region. Depending upon application, the backside substrate member can be made from various materials. For example, the backside member is characterized by a polymer material.

In yet another embodiment, the present invention provides a solar cell apparatus that includes a backside substrate member. The backside substrate member includes a backside surface region and an inner surface region. The backside substrate member is characterized by a width. For example, the backside substrate member is characterized by a length of about eight inches and less. As an example, the backside substrate member is characterized by a width of about 8 inches and less and a length of more than 8 inches. Of course, there can be other variations, modifications, and alternatives. Further details of the solar cell assembly can be found in U.S. patent application Ser. No. 11/445,933 (Attorney Docket No.: 025902-000210US), commonly assigned, and hereby incorporated by reference herein.

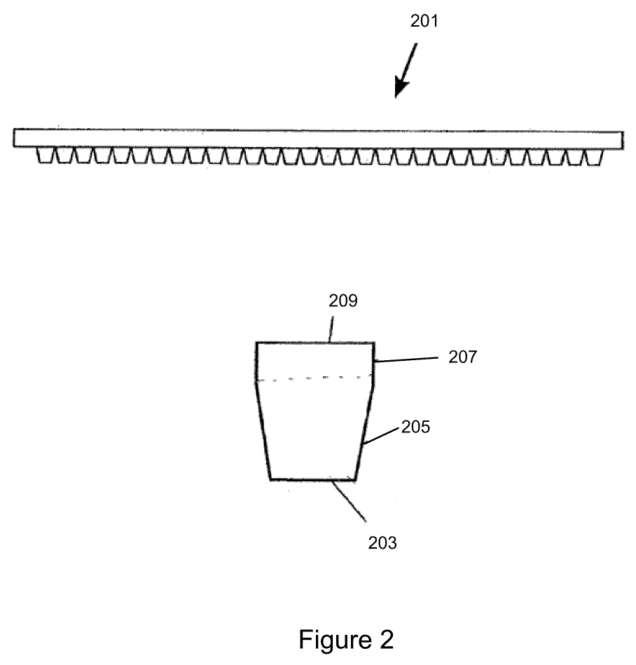

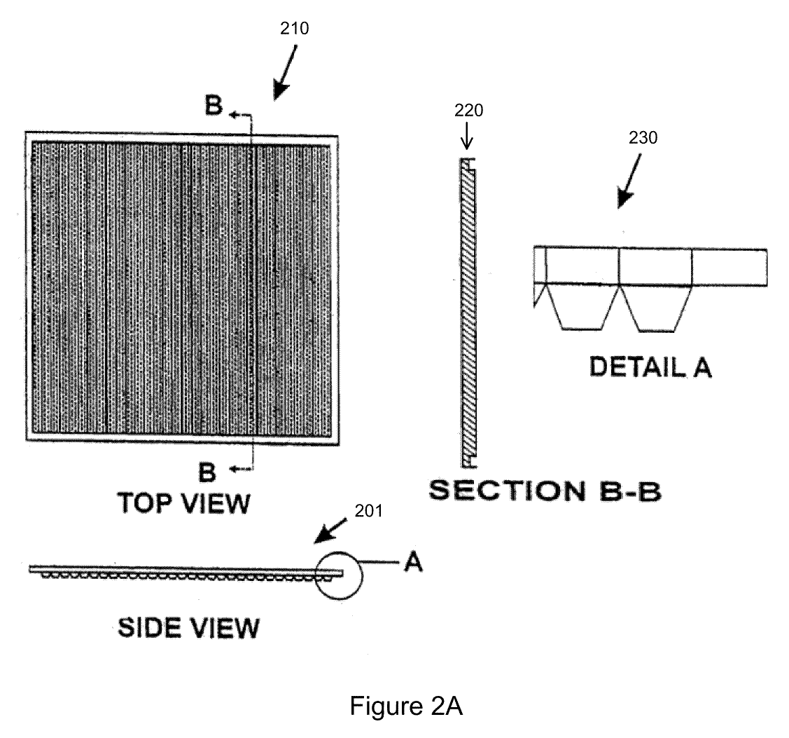

FIG. 2 is a simplified diagram of solar cell concentrating elements according to an embodiment of the present invention. This diagram is merely an example, which should not unduly limit the scope of the claims herein. One of ordinary skill in the art would recognize other variations, modifications, and alternatives. As shown, each of the concentrating elements for the strip configuration includes a trapezoidal shaped member. Each of the trapezoidal shaped members has a bottom surface 201 coupled to a pyramidal shaped region 205 coupled to an upper region 207. The upper region is defined by surface 209, which is co-extensive of the front cover. Each of the members is spatially disposed and in parallel to each other according to a specific embodiment. Here, the term “trapezoidal” or “pyramidal” may include embodiments with straight or curved or a combination of straight and curved walls according to embodiments of the present invention. Depending upon the embodiment, the concentrating elements may be on the front cover, integrated into the front cover, and/or be coupled to the front cover according to embodiments of the present invention. Further details of the front cover with concentrating elements is provided more particularly below.

In a specific embodiment, a solar cell apparatus includes a shaped concentrator device operably coupled to each of the plurality of photovoltaic strips. The shaped concentrator device has a first side and a second side. In addition, the solar cell apparatus includes an aperture region provided on the first side of the shaped concentrator device. As merely an example, the concentrator device includes a first side region and a second side region. Depending upon application, the first side region is characterized by a roughness of about 100 nanometers or 120 nanometers RMS and less, and the second side region is characterized by a roughness of about 100 nanometers or 120 nanometers RMS and less. For example, the roughness is characterized by a dimension value of about 10% of a light wavelength derived from the aperture regions. Depending upon applications, the backside member can have a pyramid-type shape.

As an example, the solar cell apparatus includes an exit region provided on the second side of the shaped concentrator device. In addition, the solar cell apparatus includes a geometric concentration characteristic provided by a ratio of the aperture region to the exit region. The ratio can be characterized by a range from about 1.8 to about 4.5. The solar cell apparatus also includes a polymer material characterizing the shaped concentrator device. The solar cell apparatus additionally includes a refractive index of about 1.45 and greater characterizing the polymer material of the shaped concentrator device. Additionally, the solar cell apparatus includes a coupling material formed overlying each of the plurality of photovoltaic strips and coupling each of the plurality of photovoltaic regions to each of the concentrator devices. For example, the coupling material is characterized by a suitable Young's Modulus.

As merely an example, the solar cell apparatus includes a refractive index of about 1.45 and greater characterizing the coupling material coupling each of the plurality of photovoltaic regions to each of the concentrator device. Depending upon application, the polymer material is characterized by a thermal expansion constant that is suitable to withstand changes due to thermal expansion of elements of the solar cell apparatus.

For certain applications, the plurality of concentrating elements has a light entrance area (A1) and a light exit area (A2) such that A2/A1 is 0.8 and less. As merely an example, the plurality of concentrating elements has a light entrance area (A1) and a light exit area (A2) such that A2/A1 is 0.8 and less, and the plurality of photovoltaic strips are coupled against the light exit area. In a preferred embodiment, the ratio of A2/A1 is about 0.5 and less. For example, each of the concentrating elements has a height of 7 mm or less. In a specific embodiment, the sealed sandwiched assembly has a width ranging from about 100 millimeters to about 210 millimeters and a length ranging from about 100 millimeters to about 210 millimeters. In a specific embodiment, the sealed sandwiched assembly can even have a length of about 300 millimeters and greater. As another example, each of the concentrating elements has a pair of sides. In a specific embodiment, each of the sides has a surface finish of 100 nanometers or less or 120 nanometers and less RMS. Of course, there can be other variations, modifications, and alternatives.

Referring now to FIG. 2A, the front cover has been illustrated using a side view 201, which is similar to FIG. 2. The front cover also has a top-view illustration 210. A section view 220 from “B-B” has also been illustrated. A detailed view “A” of at least two of the concentrating elements 230 is also shown. Depending upon the embodiment, there can be other variations, modifications, and alternatives.

Depending upon the embodiment, the concentrating elements are made of a suitable material. The concentrating elements can be made of a polymer, glass, or other optically transparent materials, including any combination of these, and the like. The suitable material is preferably environmentally stable and can withstand environmental temperatures, weather, and other “outdoor” conditions. The concentrating elements can also include portions that are coated with an anti-reflective coating for improved efficiency. Coatings can also be used for improving a durability of the concentrating elements. Of course, there can be other variations, modifications, and alternatives.

In a specific embodiment, the solar cell apparatus includes a first reflective side provided between a first portion of the aperture region and a first portion of the exit region. As merely an example, the first reflective side includes a first polished surface of a portion of the polymer material. For certain applications, the first reflective side is characterized by a surface roughness of about 120 nanometers RMS and less.

Moreover, the solar cell apparatus includes a second reflective side provided between a second portion of the aperture region and a second portion of the exit region. For example, the second reflective side comprises a second polished surface of a portion of the polymer material. For certain applications, the second reflective side is characterized by a surface roughness of about 120 nanometers and less. As an example, the first reflective side and the second reflective side provide for total internal reflection of one or more photons provided from the aperture region.

In addition, the solar cell apparatus includes a geometric concentration characteristic provided by a ratio of the aperture region to the exit region. The ratio is characterized by a range from about 1.8 to about 4.5. Additionally, the solar cell apparatus includes a polymer material characterizing the shaped concentrator device, which includes the aperture region, exit region, first reflective side, and second reflective side. As an example, the polymer material is capable of being free from damaged caused by ultraviolet radiation.

Furthermore, the solar cell apparatus has a refractive index of about 1.45 and greater characterizing the polymer material of the shaped concentrator device. Moreover, the solar cell apparatus includes a coupling material formed overlying each of the plurality of photovoltaic strips and coupling each of the plurality of photovoltaic regions to each of the concentrator devices. The solar cell apparatus additionally includes one or more pocket regions facing each of the first reflective side and the second reflective side. The one or more pocket regions can be characterized by a refractive index of about 1 to cause one or more photons from the aperture region to be reflected toward the exit region. To maintain good efficiency of the subject concentrator devices, each of the concentrating elements is separated by a region having a notch structure of a predetermined size and shape according to a specific embodiment. Further details of the notch structures can be found throughout the present specification and more particularly below.

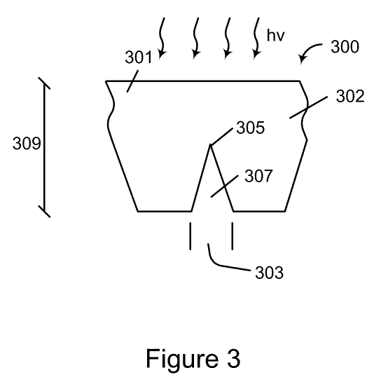

FIG. 3 is a simplified diagram of a plurality of notch structures for a solar cell concentrator 300 according to an embodiment of the present invention. This diagram is merely an example, which should not unduly limit the scope of the claims herein. One of ordinary skill in the art would recognize other variations, modifications, and alternatives. As shown, the concentrator structure has a first concentrator element 301, which includes a first aperture region and a first exit region. The concentrator structure also includes a second concentrator element 302 integrally formed with the first concentrator element. In a specific embodiment, the second concentrator element includes a second aperture region and a second exit region.

In a specific embodiment, the structure has a separation region 303 provided between the first concentrator element and the second concentrator element. The separation region is characterized by a width 303 separating the first exit region from the second exit region. Also shown is a triangular shaped region 307 including an apex 305 defined by a radius of curvature of 0.15 mm and less and a base defined by the separation region. In a specific embodiment, the triangular region has a refractive index of about one, which can be essentially an air gap and/or other non-solid open region. The apex of the triangular region is provided within a thickness of material 309 of the concentrator structure. Of course there can be other variations, modifications, and alternatives.

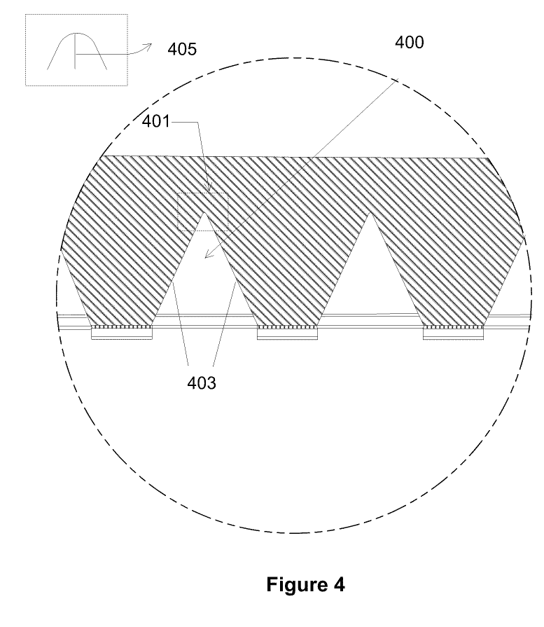

FIG. 4 is a more detailed diagram of a notch structure for a solar cell concentrator according to an embodiment of the present invention. This diagram is merely an example, which should not unduly limit the scope of the claims herein. One of ordinary skill in the art would recognize other variations, modifications, and alternatives. As shown in FIG. 4, the apex of the triangular region includes a notch structure characterized by an apex region 401 and wall regions 403. In a specific embodiment, the wall regions are straight. In certain other embodiments, the wall region may be curved. The notch structure describes a portion of a cross section of a triangular channel region provided between a first solar concentration element and a second solar concentration element. The term “notch” is not intended to be limited to the specification but should be construed by a common interpretation of the term. In a specific embodiment, the apex region is characterized by a radius of curvature 405. In a specific embodiment, the radius of curvature can be greater than about 0.001 mm. In an alternative embodiment, the radius of curvature can range from 0.05 mm to about 0.15 mm. Preferably, a minimum of radius of curvature is provided to maintain a structure/mechanical integrity of the solar cell concentrator in the temperature range of about −40 deg Celsius and 85 deg Celsius in accordance with IEC (International Electrotechnical Commission) 61215 specification according to a specific embodiment. Of course there can be other modifications, variations, and alternatives.

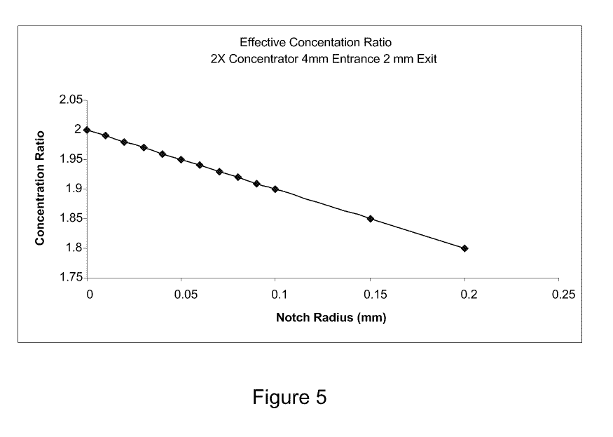

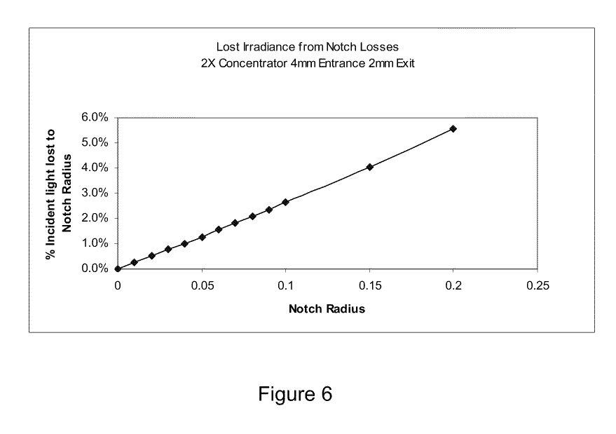

FIG. 5 is a plot of concentration ratio as a function of notch structure size of a solar cell concentrator according to an embodiment of the present invention. This diagram is merely an example, which should not unduly limit the scope of the claims herein. One of ordinary skill in the art would recognize other variations, modifications, and alternatives. As shown, the vertical axis illustrates concentration ratio and the horizontal axis illustrates notch structure size or radius of curvature. The result was obtained using a solar cell concentrator with an entrance of 4 mm and an exit of 2 mm. The concentration ratio generally decreases with an increase in radius of curvature of the apex region. A corresponding plot of irradiation loss as a function of notch size is shown in FIG. 6. As shown, the vertical axis illustrates percent of light loss or irradiation loss and the horizontal axis illustrates notch radius of curvature of the apex region. The irradiation loss generally increases with an increase of notch radius. In a specific embodiment, the radius of curvature is optimized to allow for a maximum concentration ratio or a minimum irradiation loss and to allow for maintaining mechanical/structural integrity of the solar cell concentrator in the temperature range between about −40 deg Celsius and 85 deg Celsius according to IEC 61215 specification according to a preferred embodiment.

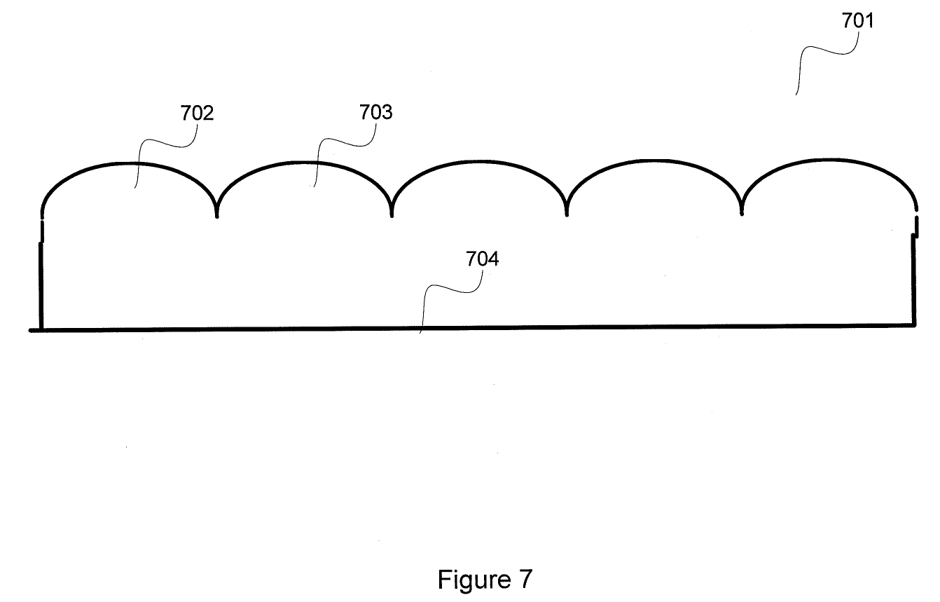

In various embodiments, the present invention provides solar panels with concentrator elements integrated with the front cover member of the solar panel. Now referring back to FIG. 1, the front cover member 121 comprises concentrator elements as shown FIG. 2. In alternative embodiments, the front cover member 121 comprises integral concentrator elements that are shown in FIG. 7, which is explained below.

FIG. 7 is a simplified diagram illustrating a solar concentrator according to embodiments of the present invention. This diagram is merely an example, which should not unduly limit the scope of the claims. One of ordinary skill in the art would recognize many variations, alternatives, and modifications.

As shown in FIG. 7, a solar concentrator 701 comprises a plurality of concentrator elements. Concentrator 702 and 703 are on an outside surface of the solar concentrator 701 for receiving and concentrating light. The inside surface 704 of the solar concentrator 701 is to be coupled to photovoltaic strips using coupling material as shown in FIG. 1. As shown in FIG. 1, concentrators 702 and 703 have a curved surface for concentrating light. Since the inside surface 704 is flat, coupling solar concentrator 701 to a solar panel is convenient.

Depending on the application, solar concentrator 701 may be formed using various types of transparent materials. In one embodiment, solar concentrator 701 consists essentially of glass material. In another embodiment, polymeric material is used for forming solar concentrator 701.

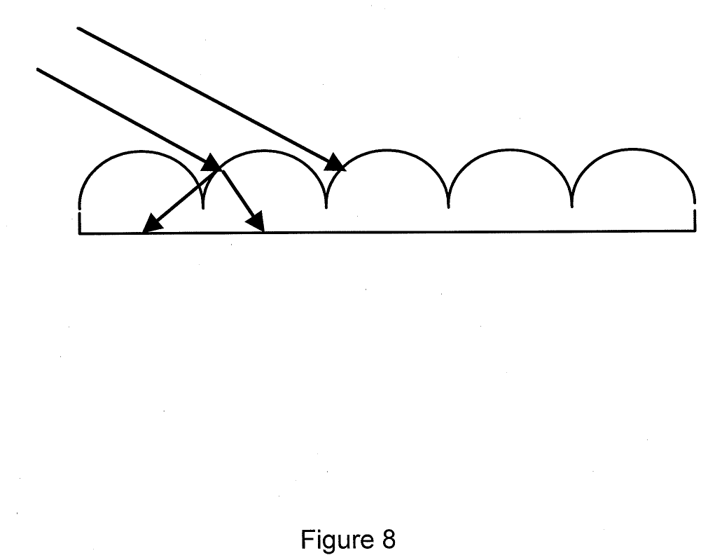

FIG. 8 is a simplified diagram illustrating the operation of a solar concentrator according to an embodiment of the present invention. This diagram is merely an example, which should not unduly limit the scope of the claims. One of ordinary skill in the art would recognize many variations, alternatives, and modifications.

As shown in FIG. 8, light incident to a concentrator element occurring at a steep angle is directed to two different locations, both of which can be collected by a photovoltaic region underneath. It is to be appreciated that with off angle light occurring at steep angles across the length of the optics of the concentrator module, more light enters a solar module. The steep angles of incidence with flat glass allow for large Fresnel reflections. The curved shape of the concentrator means that there are always surface areas that are substantially normal to the light. Additionally, the concentrator structure as shown allows reflected light an opportunity to re-enter the solar module and to be collected by the photovoltaic region underneath.

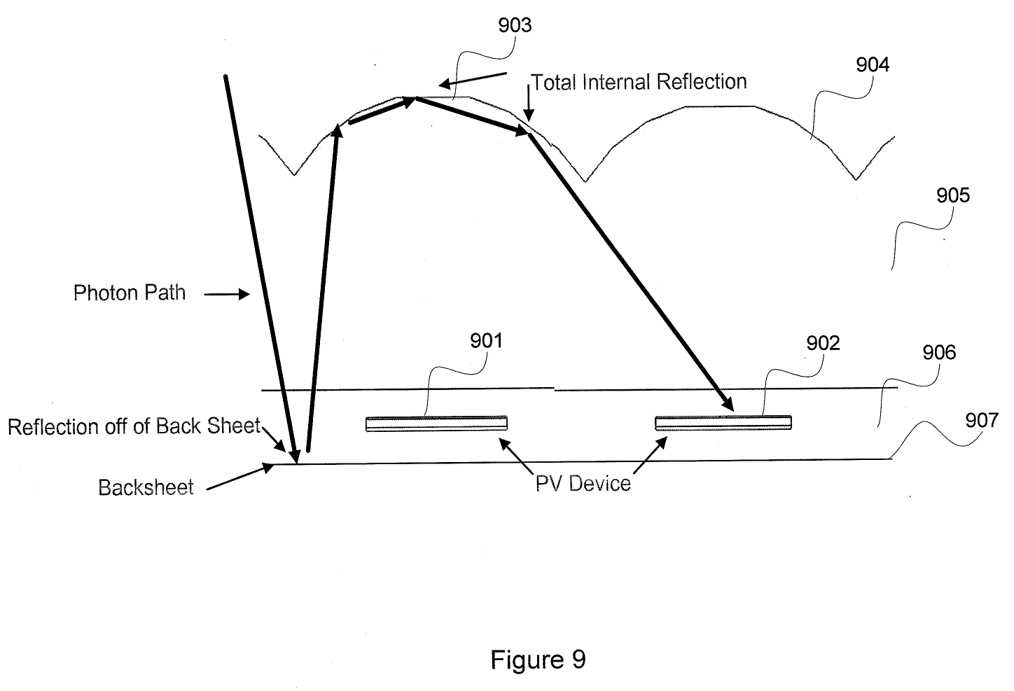

FIG. 9 is a simplified diagram illustrating the operation of a solar panel with solar concentrator according to an embodiment of the present invention. This diagram is merely an example, which should not unduly limit the scope of the claims. One of ordinary skill in the art would recognize many variations, alternatives, and modifications.

As shown in FIG. 9, a solar concentrator 905 comprises solar concentrator elements 903 and 904. The concentrator elements 903 and 904 are characterized by a curved shape, with a flat region at the top. It is to be appreciated that the geometric shape of the concentrator elements is optimized for light gathering. Photovoltaic strips 901 and 902 are respectively aligned to the solar concentrators 903 and 904 as shown in FIG. 9. For example, the photovoltaic strips are parts of the electrically connected photovoltaic package similar to photovoltaic strips 105 shown in FIG. 1. A reflective back cover member 907 is provided as shown. In various embodiments, the photovoltaic strips 901 and 902 are secured between the back cover member 907 and the solar concentrator 905 using coupling material 906. For example, the coupling material comprises EVA material.

The shape of concentrators and their alignments with the photovoltaic strips is optimized to allow the photovoltaic strips to capture as much photovoltaic energy as possible. As shown in FIG. 9, a photon that does not initially make its way to a photovoltaic strip is reflected by back sheet 907 to concentrator 903, and concentrator 903 reflects the photon to photovoltaic strip 902, which can capture the photon and generate energy. It is to be appreciated that in various embodiments, solar concentrator 905 and back sheet 907 together maximizes total internal reflection, thereby increasing the chances of photon being captured by the photovoltaic strips. For example, stray light that misses the PV device is reflected from the back sheet. Much of the reflected back sheet light is then reflected (e.g., total internal reflection) within the module. Light will reflect around within the module until it either hits the PV and is converted to electricity, exits the module, or is absorbed in the glass, EVA, or back sheet.

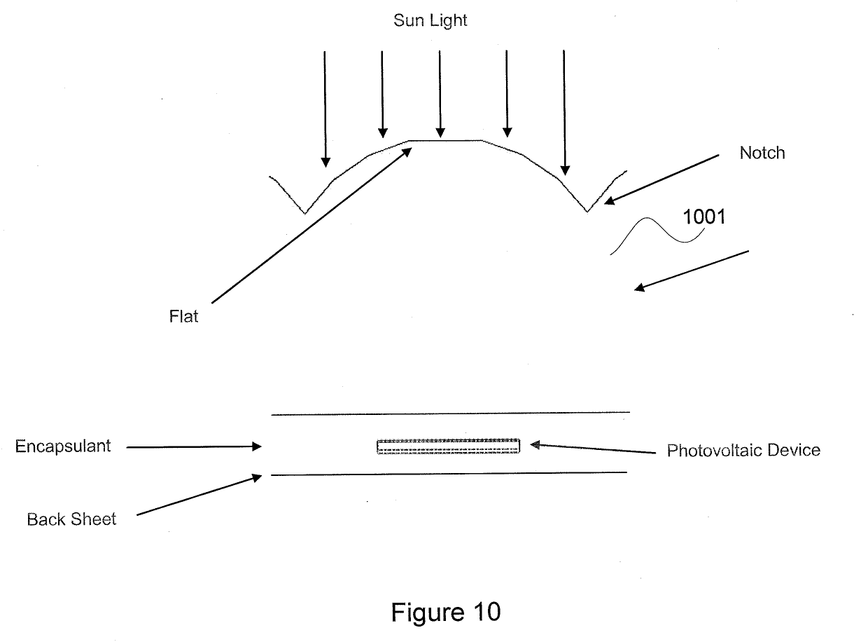

FIG. 10 is a simplified diagram illustrating the shape of a concentrator element in relation to a photovoltaic device according to an embodiment of the present invention. This diagram is merely an example, which should not unduly limit the scope of the claims. One of ordinary skill in the art would recognize many variations, alternatives, and modifications.

As shown in FIG. 10, a concentrator element 1001 includes a flat portion at the top of its curvature. The flap portion at the top of the concentrator element 1001 allows light to be directly transmitted to the photovoltaic device aligned underneath. Concentrator element 1001 shares notches with adjacent concentrator elements.

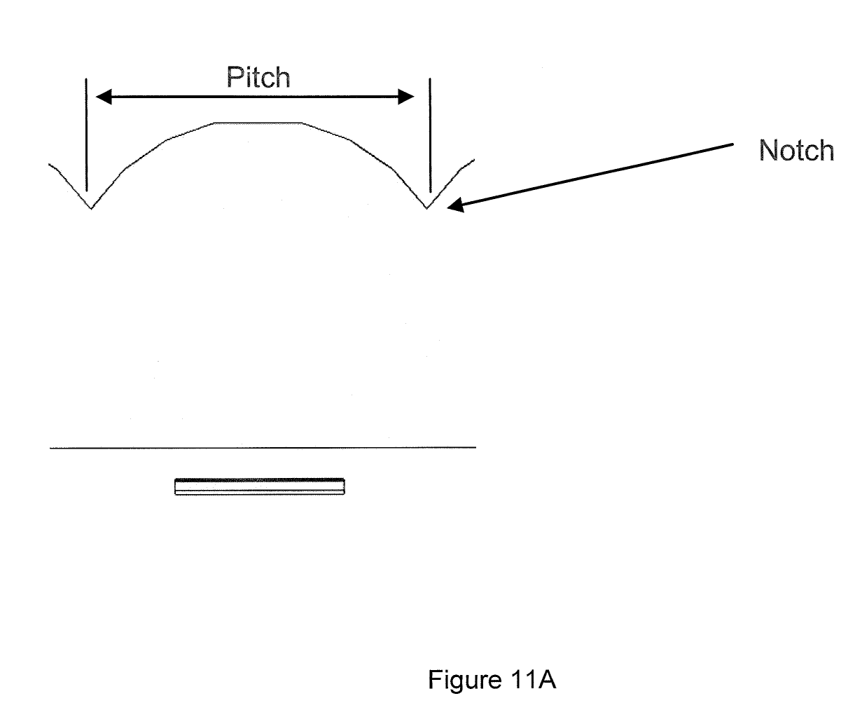

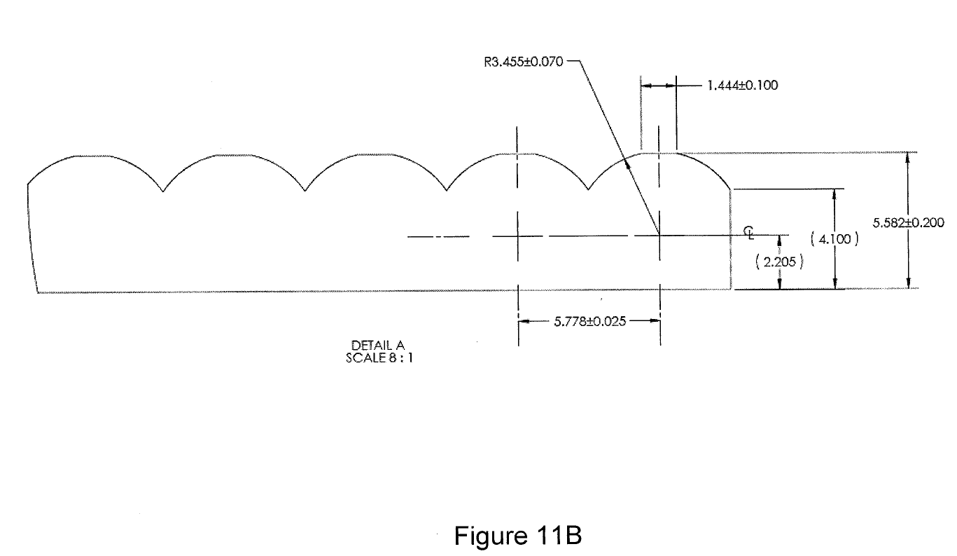

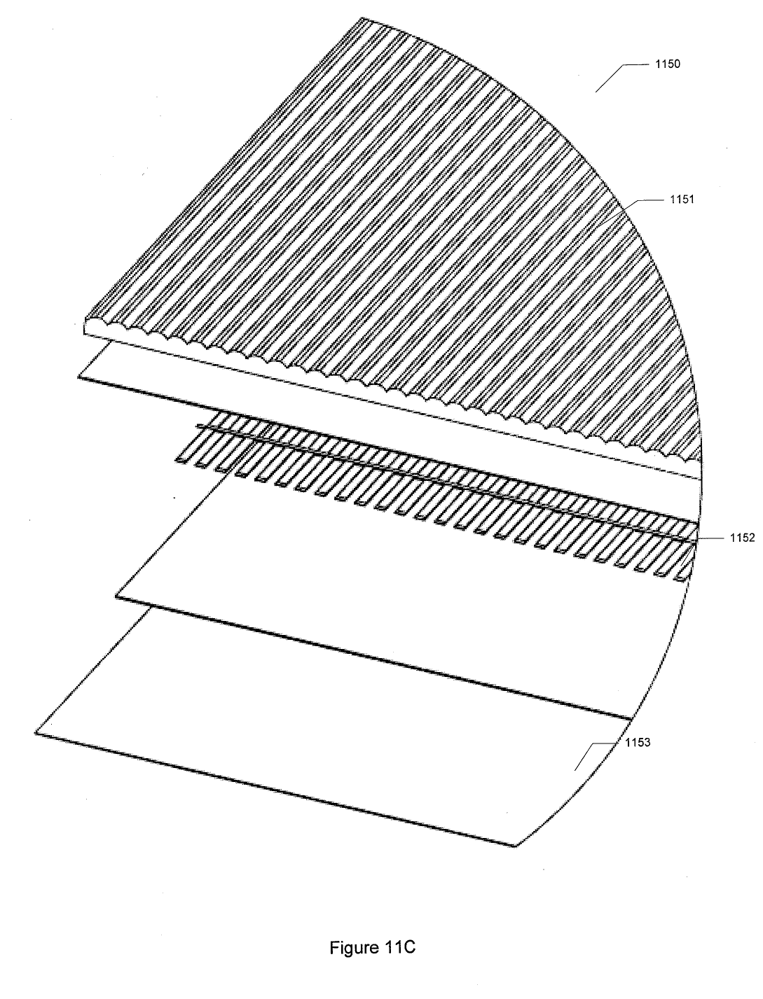

FIGS. 11A and 11B are simplified diagrams illustrating shapes and dimensions of concentrator elements according to an embodiment of the present invention. These diagrams are merely examples, which should not unduly limit the scope of the claims. One of ordinary skill in the art would recognize many variations, alternatives, and modifications.

Illustrated in FIG. 11A, a concentrator element is characterized by a pitch dimension and a notch that it shares with the adjacent concentrator elements. For example, notch and pitch are both loss mechanisms. In a specific embodiment, the notch is characterized by a 0.2 mm notch radius. For example, a 0.2 mm notch radius translates to a 7% power loss with a 5.778 mm pitch. In one specific embodiment, the pitch size is manufactured within a 100 micron consistency, and this particular pitch size causes 1.8% power loss for the module.

FIG. 11B illustrates the specific dimensions of a solar concentrator according to a specific embodiment. As an example, the numerical dimensions shown are in millimeters for the concentrator element. Depending on the application, the solar concentrator as shown may be scaled up or down. For example, a solar concentrator may be characterized by a surface area of over 1 m², and a number of concentrator elements with dimensions shown in FIG. 11B occupy essentially the entire area of the solar concentrator.

FIG. 11C is a simplified diagram providing an exploded view of a concentrated solar panel according to an embodiment of the present invention. This diagram is merely an example, which should not unduly limit the scope of the claims. One of ordinary skill in the art would recognize many variations, alternatives, and modifications. As shown in FIG. 11C, a concentrated solar panel 1150 includes a concentrator 1151, a photovoltaic assembly 1152, and a back cover member 1153. For example, the components of the concentrated solar panel 1150 are coupled together by encapsulating material.

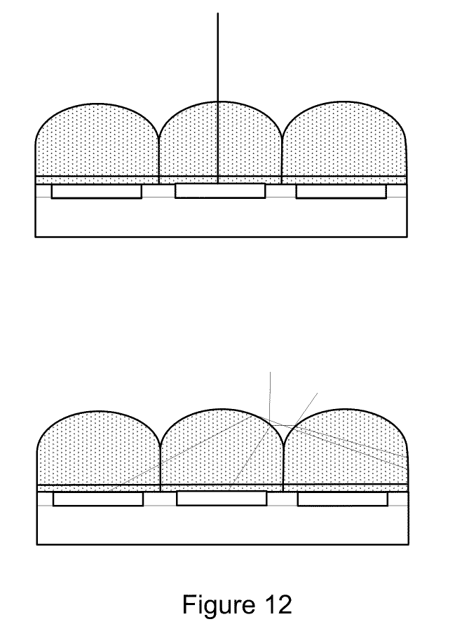

FIGS. 12-16 are diagrams illustrating the optical properties of concentrator elements according to embodiments of the present invention. These diagrams are merely examples, which should not unduly limit the scope of the claims. One of ordinary skill in the art would recognize many variations, alternatives, and modifications.

As shown in FIG. 12, a ray of light may reflect or refract in various ways. Shown on the left side, when a ray of light is transmitted to the flat region of the concentrator element at a right angle, the light passes directly to the photovoltaic region underneath. On the other hand, when a ray of light is transmitted to the curved region of the concentrator element at a right angle, the light may be reflected and/or refracted, depending on various factors, such as angle of the curvature, lens refraction determined by refractive index difference, etc. For example, refraction and the incident angle determine how much the light will bend. Some of the refracted light is transmitted to the photovoltaic region, while the remaining refractive light is reflected by the reflective back cover and later captured by one or more photovoltaic regions after internal reflection.

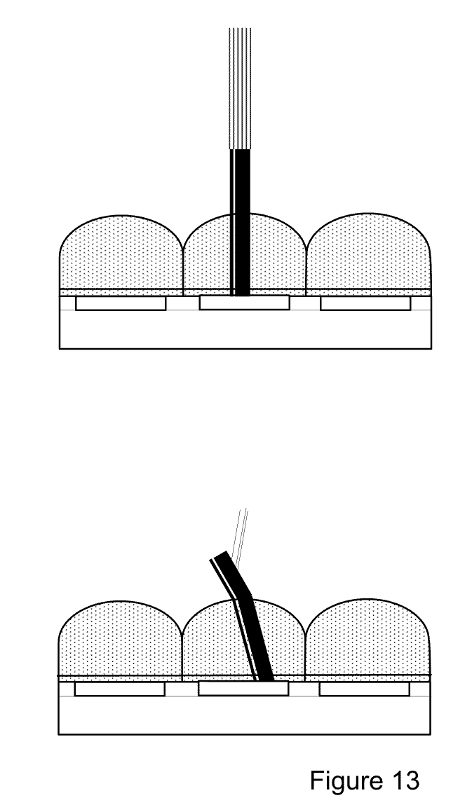

It is to be appreciated that the size and the alignment of the photovoltaic regions are optimized in light of the concentrator elements. As illustrated in FIG. 13, when a ray of light is transmitted to the flat region of the concentrator element at a right angle, the light passes directly to the photovoltaic region underneath. In various embodiments, the width of the photovoltaic regions is greater than the flat region of concentrator elements. As a result, light that enters the flat region of the concentrator module at a small angle (e.g., 10 degrees) is still captured by the photovoltaic region.

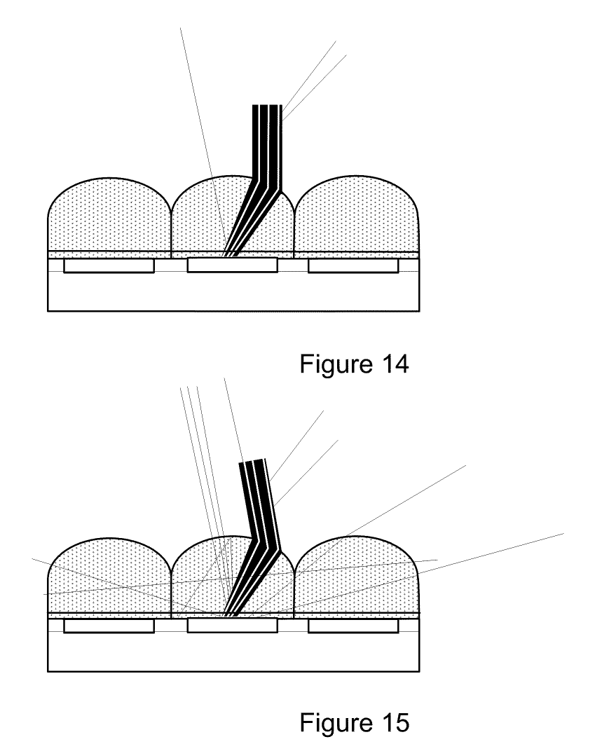

FIG. 14 illustrates the path of light entering the curved region of the concentrator at a right angle. As shown, the light passes to the photovoltaic region underneath.

FIG. 15 illustrates the path of light entering the curved region of the concentrator at a small angle off the right angle (e.g., off the right angle by 10 degrees). Depending on the location and the angle, some of the light is transmitted to the photovoltaic region underneath. In some cases, when the light is not transmitted to the photovoltaic region, the light is transmitted to the reflective back sheet, from where the light is reflected by the reflective back cover and later captured by one or more photovoltaic regions after internal reflection. For example, the internal reflection and subsequent capturing of light are illustrated in FIG. 9 and explained above.

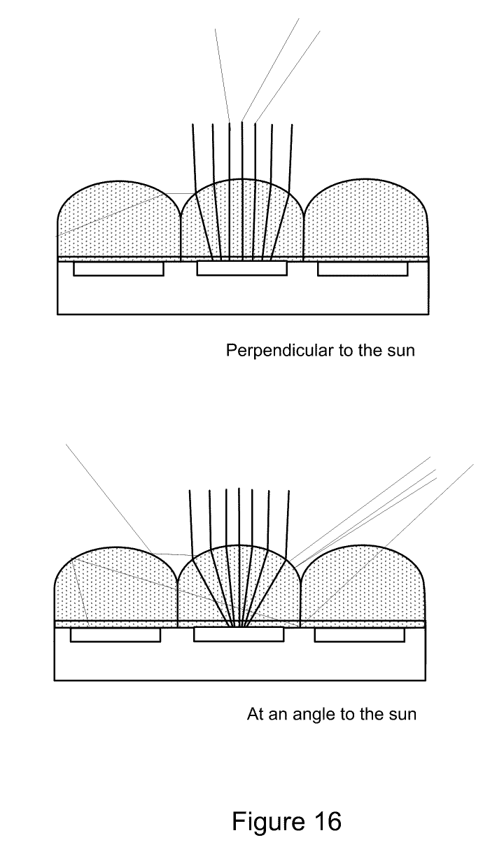

The flat top region of the concentrator provides various benefits. Among other things, a flat top region allows even light distribution no matter at what angle the light enters. In other embodiments, concentrator elements are semi-spherical and do not have the flat top regions. As shown in FIG. 16, the curved shape allows the concentrator module to direct the sunlight to the photovoltaic region underneath both when the concentrator element is perpendicular to the sun or at an angle to the sun. For example, when module is perpendicular to the sun, light is evenly distributed across the PV device. As the angle of the sun parallel to the troughs begins to increase, the light becomes focused on a smaller area of the PV device. It is to be appreciated that the curved shape without flat region for the concentrator elements may be associated with some disadvantages, such as higher heat concentration, greater distances to the current collection and conduction locations, the possibility of an increased series resistance (e.g., current must traverse dark PV), and the possibility of over-concentrating light on a undesirable location. flat region allows for easy for lamination because of the flat top. In addition, the flat region reduces weight of concentrators, as a portion of the concentrator material is “shaved off” from an essentially round top region. Additionally, the flat top provides the benefits of convenient stacking, thereby allowing easy storage and transportation. At the performance level, the flat top regions also improve thermal conductivity.

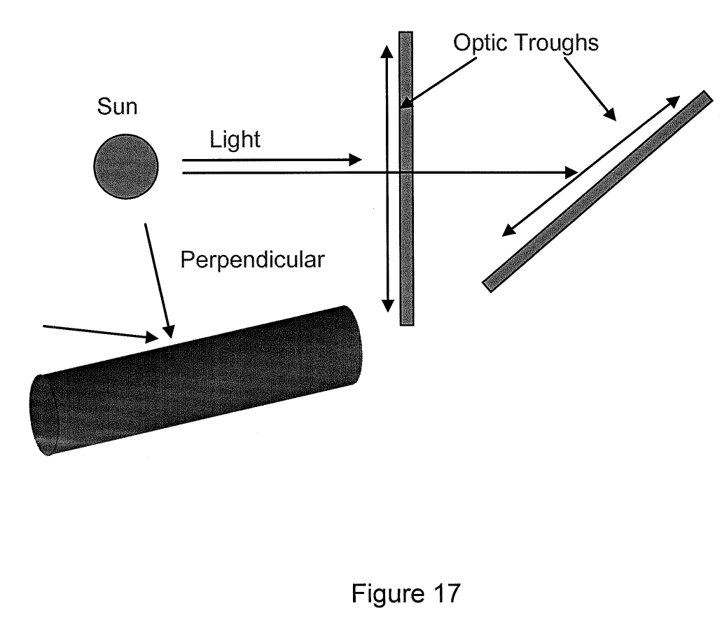

FIG. 17 is a simplified diagram illustrating a curved concentrator shape according to an embodiment of the present invention.

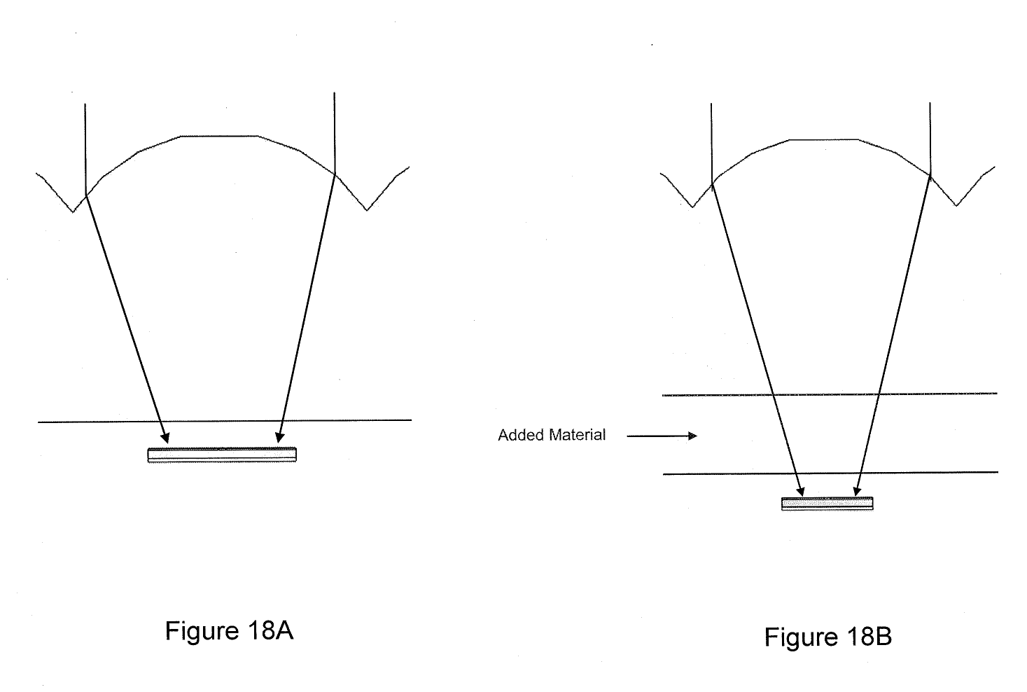

It is to be appreciated that the concentrator elements according to the embodiments of the present invention can be used to provide different concentrator ratios. FIGS. 18A and 18B are simplified diagrams illustrating solar panel designs where the same concentrator design is used to provide different concentrator ratios according to an embodiment of the present invention. These diagrams are merely examples, which should not unduly limit the scope of the claims. One of ordinary skill in the art would recognize many variations, alternatives, and modifications. As shown in FIGS. 18A and 18B, the same lens design is used for different concentration ratios. By increasing the distance between the concentrator element and the photovoltaic region, the concentrator ratio is increased as well. For example, the principle of concentration ratio is based on the optical principle that focus length is directly proportional to magnification or concentration ratio.

As shown in FIG. 18B, the distance between the concentrator element and the photovoltaic region is greater than that shown in FIG. 18A. In various embodiments, added material is used to increase the distance. For example, the added material can be glass, EVA, optical encapsulants, optical polymers, and others. As shown, the added material moves the photovoltaic region closer to the focal point therefore utilizing less PV material. In a specific embodiment, the photovoltaic region is moved away from the focal point to utilize more silicon, which can be good for diffuse light locations.

It is to be appreciated that the distance between the concentrator element and the photovoltaic region may be increased in other ways as well. For example, the thickness of the solar concentrator may be increased, thereby increasing the distance between the concentrator element and the photovoltaic region.

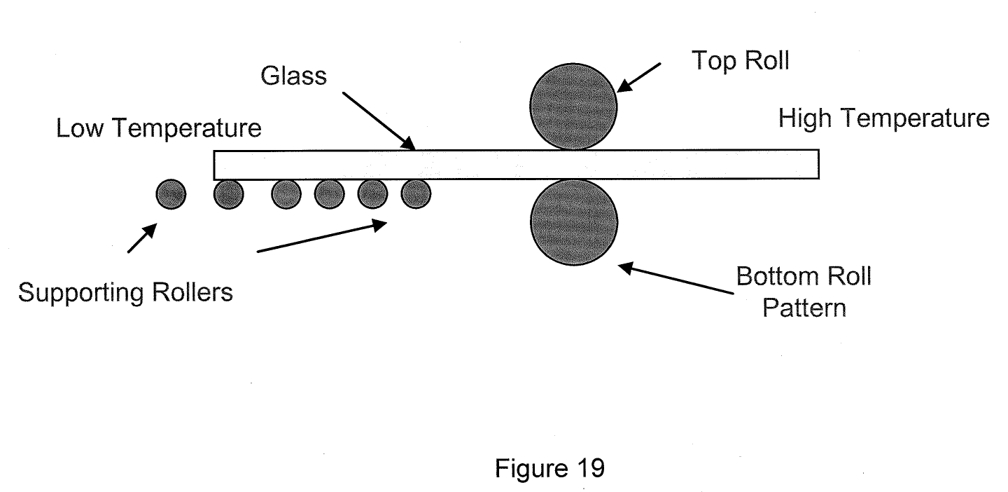

In one embodiment, the solar concentrator is manufactured by shaping a single piece of glass material. As an example, curved patterns are formed on a flat piece of glass material by patterning the glass material under high temperatures. FIG. 19 is a simplified diagram illustrating a process for forming solar concentrator according to an embodiment of the present invention. This diagram is merely an example, which should not unduly limit the scope of the claims. One of ordinary skill in the art would recognize many variations, alternatives, and modifications.

As described above, solar concentrators are manufactured using various types of materials. According to various embodiments, solar concentrators are manufactured using glass material. In a specific embodiment, a solar concentrator (which includes a plurality of integral solar concentrator elements) comprises a piece of glass material with a thickness of 4.5 mm or greater. For example, the 4.5 mm thickness is greater than the 4 mm or thinner thickness typically of convention solar panel glasses. Among other things, the 4.5 mm thickness provides strengths and allows for integration of solar concentrator elements. For example, the 4.5 mm thickness of the glass used for the solar concentrators provides strength against heavy snow loads, hurricanes, and other elements of nature.

In one embodiment, the solar concentrators are manufactured by shaping a flat piece of glass. As shown in FIG. 19, a pattern for the concentrator elements is provided on the bottom surface of glass during manufacturing. Glass is annealed from high temperature to low temperature on rollers. Among other things, the rollers are designed to support the weight of the glass during the shaping process. The glass becomes malleable at high temperatures, which allows patterning to take place. The flat on top of the lens helps spread the weight of the glass across the rollers and allows for flatter and more repeatable glass. Once patterned and cooled, the patterned glass becomes a solar concentrator with a plurality of solar concentrator elements. The solar concentrator is then incorporated into a solar panel.

It is to be appreciated that glass concentrators may be manufacturing using glass of various thickness and design specifications. Among other things, the glass concentrators are optimized to save cost and weight. In various embodiments, the sheet glass used for manufacturing the glass concentrators is characterized by a thickness of at least 3 mm. For example, the 3 mm thickness is a minimum that can be easily tempered and provide the structural strength needed for the application and to pass certification. For example, at a minimum, the modules have to be able to handle a load of at least 2400 Pascals.

For various applications, thicker glasses (e.g., around 6 mm and up to 12 mm) may be used as well. For example, the thickest glass in use today is double glass modules (front and back).

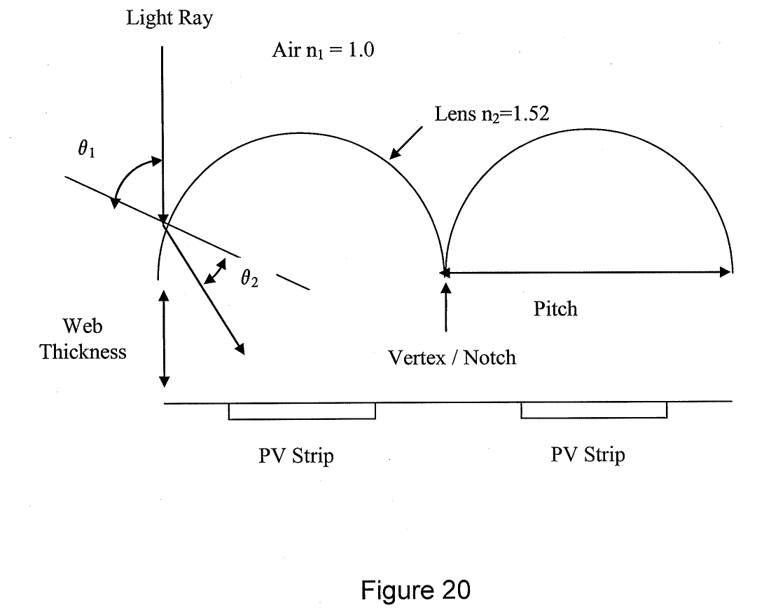

FIG. 20 is a simplified diagram illustrating a glass concentrator design according to an embodiment of the present invention. This diagram is merely an example, which should not unduly limit the scope of the claims. One of ordinary skill in the art would recognize many variations, alternatives, and modifications. As shown in FIG. 20, the thickness of sheet glass used in manufacturing the glass concentrator contributes to the web thickness of the glass concentrator as illustrated in FIG. 20. By changing the web thickness, the concentration ratio may be adjusted. For example, the concentration ratio is directly proportional to the web thickness. Various types of filler material may be used to increase the web thickness (e.g., EVA filler material described above). Using glass sheets with different web thickness also changes the concentration ratio. For example, thick glass sheets are used for high concentration ratio, and thin glass sheets are used for low concentration ratio.

As shown in FIG. 20, various concentration ratios are achieved by varying pitch, radius of curvature, index of refraction, and thickness. For example, the index of refraction of air is n₁=1.0, glass is approximately 1.52. Under the Snell's Law, n₁ Sin θ₁=n₂ Sin θ₂ defines how the light is redirected.

In a preferred embodiment, the photovoltaic (“PV”) strip width is 75% or less of the pitch shown in FIG. 20. In a specific embodiment, the PV strip width relative to the lens pitch is about 54%. In certain embodiment where high concentration ratio is used, the PV strip width relative to the lens pitch of is 33% or lower.

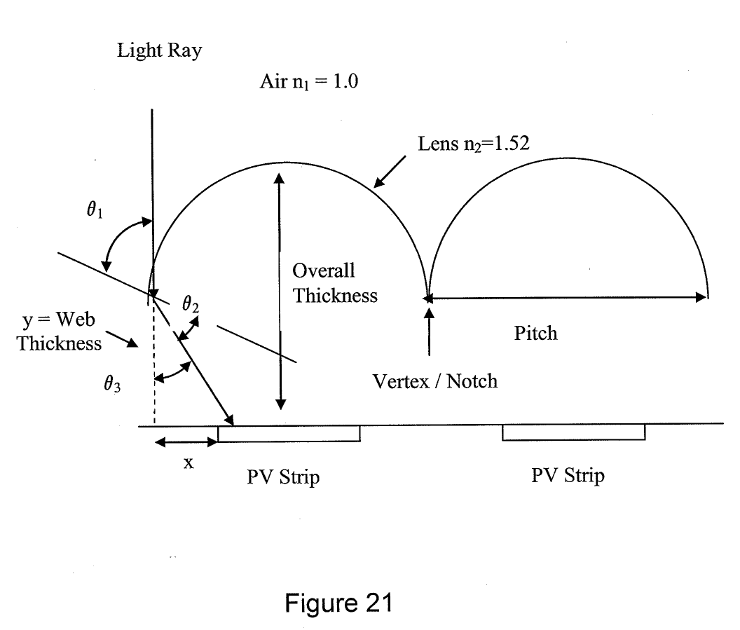

In various embodiments, various geometric ratios among glass concentrator dimensions are calculated using formulae provided below and illustrated in FIG. 21. FIG. 21 is a simplified diagram illustrating geometry of glass concentrator according to embodiments of the present invention. This diagram is merely an example, which should not unduly limit the scope of the claims. One of ordinary skill in the art would recognize many variations, alternatives, and modifications.

As illustrated in FIG. 21, the direct rays (e.g., rays that are perpendicular to the module) that enter the lens are focused an area that is equal to the size of the PV strip or less. The light rays that enter near the vertex (or notch) are the ones that determine the thickness of the glass. For example, depending on the angle of the glass to the direct rays at the vertex, the light is redirected according to Snell's law. The glass is thick enough for the redirected ray to hit the PV. For example, the minimum web thickness that can be achieved would be determined by the following formula, where θ₂ is the redirect light angle and θ₁ is the angle between the incoming light ray and the normal to the glass:

θ₂=Sin⁻¹(n₁/n₂*Sin θ₁)

Also, the desired ratio of PV strip width and lens pitch is determined by the following equation:

W ratio=(PV Strip Width)/lens pitch

Where

θ₃=θ₁−θ₂

x=((lens pitch)−(PV strip width)*(AOI multiplier)/2

The minimum web thickness ‘y’ is y=x/(tan(θ₃)

For example, the shape of the lens varies across the pitch as long as the thickness of the glass ensures that all direct rays will hit the PV strip. Depending on the application, embodiments of the present invention provides that lens shape can be elliptical, circular, repeating patterns, and/or random lens profiles. As described above, one or more area of the lens to can be flat.

As the PV strip size decreases, the distance x increases and thus the web thickness increases for all other items being equal.

In certain embodiment, it is possible to increase the glass thickness more than the equation above in order to improve the angle of incidence of the module (“AOI”). For example, the angle of incidence of the module allows for some misalignment to the direct sun rays without losing significant performance. To achieve this, the direct light rays needs to land further within the PV Strip than the absolute condition of getting to the edge. In this case, an AIO multiplier between 0 and 1 is used. For example, a value of 80% will allow for some misalignment of the module to the direct light ray without having the light miss the PV strip.

It is to be appreciated that while the equations give exact numbers, quite often the glass is not manufactured exactly to design. This is especially true for the lens profile and the glass thickness. In many cases, to achieve a robust design and a safety margin, the glass is made a little thicker than the equation stated above. This is usually in the range of 1% to 10% of the web thickness.

According to one embodiment, a method for manufacturing a solar cell is provided. For example, the solar cell includes a glass solar concentrator manufactured according to a process described above and illustrated in FIG. 19. The method includes providing a piece of glass material, the piece of glass material being substantially flat, the piece of glass having a first surface and a second surface. For example, the piece of glass is characterized by an area of greater than 1 square meter. The piece of glass may be provided in other dimensions as well. For example, the size and dimensions of the glass conform to various standard solar panel sizes.

The method also includes providing a pattern for forming concentrator elements on the glass material. The method further includes overlaying the piece of glass on the pattern, the first surface contacting the pattern. The method includes subjecting the piece of glass to a high temperature. The method includes forming a first concentrator element and a second concentrator on the first surface, the first concentrator element having a first curved surface, the first curved surface being characterized by a radius of curvature of at least 2 mm, the curved surface having a first flat region of at least 1 mm, the flat region being at least 4 mm from the inside surface. Depending on the application, the second surface may be flattened using various methods, such as using a top roll. In one embodiment, the glass with concentrators is annealed.

The method further includes providing a first photovoltaic strip and a second photovoltaic strip on the second surface of the piece of glass material, the first photovoltaic strip and the second photovoltaic strip being respectively aligned to the first concentrator element and the second concentrator element. In one embodiment, the photovoltaic strips are electrically coupled and aligned based on predetermined spacing prior to aligning to the concentrator elements. The method includes providing transparent material for coupling the first photovoltaic strip to the piece of glass material. For example, the transparent material comprises EVA material. In one embodiment, the EVA material is cured. The method also includes providing a back cover. In an embodiment, the back cover includes a reflective back sheet.

It is to be appreciated that the above method for manufacturing a solar cell may be modified, and various steps as described may be added, removed, modified, replaced, rearranged, repeated, and overlapped.

It is also understood that the examples and embodiments described herein are for illustrative purposes only and that various modifications or changes in light thereof will be suggested to persons skilled in the art and are to be included within the spirit and purview of this application and scope of the appended claims.

What is claimed is:

1. A solar cell concentrator structure, the solar cell concentrator structure comprising:
an outside surface;
an inside surface, the inside surface being substantially flat;
a first concentrator element integrally formed on the outside surface, the first concentrator element having a first curved surface, the curved surface being characterized by a radius of at least 1 mm, the curved surface having a first flat region of at least 0.25 mm, the flat region being at least 2 mm from the inside surface;
a second concentrator element integrally formed with the first concentrator element and the outside surface, the second concentrator element including a second curved surface and a second flat region;
a separation region provided between the first concentrator element and the second concentrator element, the separation region being characterized by a width of at least 2 mm separating the first flat region from the second flat region; and
a refractive index of about 1 characterizing the separation region.

2. The structure of claim 1 further comprising a notch between the first and second concentrator elements.

3. The structure of claim 1 wherein the outside surface is characterized by a total area of more than 0.5 m².

4. The structure of claim 1 wherein the first concentrator element is characterized by a pitch size of about 3 to 8 mm.

5. The structure of claim 1 wherein the separation region is characterized by a notch radius of about 0.5 to 0.3 mm.

6. The structure of claim 1 wherein the radius of curvature is about 2.7 mm and greater.

7. The structure of claim 1 wherein the first concentrator element integrally formed with the second concentrator element is essentially a single piece of glass material.

8. The structure of claim 1 wherein the first concentrator element integrally formed with the second concentrator element is essentially a single piece of polymeric material.

9. The structure of claim 1 wherein the first concentrator element integrally formed with the second concentrator element is molded glass material.

10. The structure of claim 1 wherein the radius of curvature reduces a scattering effect of a portion of the incident electromagnetic radiation.

11. The structure of claim 1 wherein the first concentrator element and the second concentrator element are characterized by a refractive index of about 1.4 and greater.

12. The structure of claim 1 wherein the first concentrator element is optically coupled to a first photovoltaic region and the second concentrator element is optically coupled to a second photovoltaic region.

13. A solar cell concentrator structure, the solar cell concentrator structure comprising:
a piece of optical material characterized by a first spatial direction and a second spatial direction, the first spatial direction being normal to the second spatial direction;
a first concentrator element and a second concentrator element integrally formed on a first portion of the piece of optical material and a second portion of the piece of optical material, respectively, defined along the second spatial direction, the first concentrator element having a first curved surface, the first curved surface being characterized by a radius of curvature of at least 1 mm, the curved surface having a first flat region of at least 0.25 mm, the flat region being at least 4 mm from the inside surface;
an aperture region provided on the first curved surface, the curved surface being adapted to allow electromagnetic radiation to be illuminated thereon;
an exit region provided on a second surface region of the piece of optical material, the exit region being adapted to allow electromagnetic radiation to be outputted, the second surface region being substantially flat; and
a separation region provided between the first concentrator element and the second concentrator element.

14. The structure of claim 13 wherein the piece of optical material is a glass material.

15. The structure of claim 13 wherein the piece of optical material is provided with at least two patterns to define the first concentrator element and the second concentrator element.

16. The structure of claim 13 wherein the radius of curvature reduces a scattering effect of a portion of the incident electromagnetic radiation.

17. The structure of claim 13 wherein the piece of optical material is characterized by a refractive index of about 1.4 and more.

18. The structure of claim 13 wherein the first concentrator element is optically coupled to a first photovoltaic region and the second concentrator element is optically coupled to a second photovoltaic region.

19. The structure of claim 13 wherein the separation region has a refractive index of about 1.

20. The structure of claim 13 wherein the separation region is characterized by a notch radius of about 0.2 mm.

21. The structure of claim 13 wherein the first surface is a continuous and substantially flat surface.

22. The structure of claim 13 wherein the first concentrator is characterized by a width of about 4 to 6 mm.

23. A method for manufacturing a solar cell, the method comprising:
providing a piece of glass material, the piece of glass material being substantially flat, the piece of glass having a first surface and a second surface;
providing a pattern for forming concentrator elements on the piece of glass material;
overlaying the piece of glass on the pattern, the first surface contacting the pattern;
subjecting the piece of glass to a high temperature;
forming a first concentrator element and a second concentrator on the first surface, the first concentrator element having a first curved surface, the first curved surface being characterized by a radius of curvature of at least 1 mm, the curved surface having a first flat region of at least 0.25 mm, the flat region being at least 4 mm from the inside surface;
providing a first photovoltaic strip and a second photovoltaic strip on the second surface of the piece of class material; the first photovoltaic strip and the second photovoltaic strip being respectively aligned to the first concentrator element and the second concentrator element; and
providing a back cover.

24. The method of claim 23 further comprising:
determining a first measurement for the first concentrator element;
calculating a thickness based the first measurement;
shaping the piece of glass material to the calculated thickness.

25. The method of claim 23 further comprising providing transparent material for coupling the first photovoltaic strip to the piece of glass material.

26. The method of claim 23 further comprising providing EVA material for coupling the first photovoltaic strip to the piece of glass material.

27. The method of claim 23 further comprising annealing the piece of glass.

28. The method of claim 23 further wherein the piece of glass is characterized by a surface area of at least 1 m².

29. The method of claim 23 further comprising electrically coupling the first and second photovoltaic strips.

30. The method of claim 23 further comprising providing a plurality of supporting rollers for supporting the piece of glass.

31. The method of claim 23 further comprising flattening the second surface.

32. The method of claim 23 further comprising:
providing EVA material for coupling the first photovoltaic strip to the piece of glass material;
curing the EVA material.

33. The method of claim 23 further comprising defining a distance between the first concentrator element and the first photovoltaic strip, the distance being associated with a predetermined concentration ratio.

34. The method of claim 23 wherein the piece of glass is characterized by a thickness of at least 4 mm.

35. The method of claim 23 wherein the back cover comprises a back sheet coupled to the first photovoltaic strip using an EVA material.

36. The method of claim 23 wherein the back cover comprises a reflective back sheet.

37. A solar cell concentrator structure, the solar cell concentrator structure comprising:
an outside surface;
an inside surface, the inside surface being substantially flat;
a first concentrator element integrally formed on the outside surface, the first concentrator element having a first curved surface, the first concentrator element being characterized by a web thickness, the curved surface being characterized by a pitch width, the pitch width being at least 1.33 times wider than a photovoltaic strip width;
a second concentrator element integrally formed with the first concentrator element and the outside surface, the second concentrator element including a second curved surface and a second flat region, the second concentrator element sharing notch with the first concentrator element;
a separation region provided between the first concentrator element and the second concentrator element; and
a refractive index of about 1 characterizing the separation region.

38. The solar cell concentrator structure of claim 37 wherein the solar cell concentrator structure is characterized by a thickness of less than 12 mm.

39. The solar cell concentrator structure of claim 37 wherein the web thickness is a function of a concentration ratio.

40. The solar cell concentrator structure of claim 37 wherein the curved surface having a first flat region.
